(19) United States
(12) Patent Application Publication
(10) Pub. No.: US 2024/0213041 A1
(43) Pub. Date: Jun. 27, 2024

(54) SUBSTRATE PROCESSING DEVICE

(71) Applicant: SEMES CO., LTD., Cheonan-si (KR)

(72) Inventors: Taeshin KIM, Suwon-si (KR); Youngdae CHUNG, Incheon-si (KR); Chengyeh HSU, Busan-si (KR); Thomas Jongwan KWON, Seongnam-si (KR)

(73) Assignee: SEMES CO., LTD., Cheonan-si (KR)

(21) Appl. No.: 18/543,499

(22) Filed: Dec. 18, 2023

(30) Foreign Application Priority Data
Dec. 22, 2022 (KR) 10-2022-0182172

(51) Int. Cl. H01L 21/67; C23C 16/48

(52) U.S. Cl. CPC H01L 21/67017; C23C 16/483

(57) ABSTRACT

A substrate processing device includes a substrate support portion supporting a substrate, a fluid supply portion arranged above the substrate support portion and configured to supply an initiator and a monomer toward the substrate, and a laser generation portion configured to irradiate a laser in a direction intersecting a direction in which the initiator and the monomer are supplied and parallel to a surface of the substrate, wherein the initiator and the monomer are polymerized by the laser and deposited on the substrate.

### CROSS-REFERENCE TO RELATED APPLICATION

This application claims the benefit of Korean Patent Application No. 10-2022-0182172, filed on Dec. 22, 2022, in the Korean Intellectual Property Office, the disclosure of which is incorporated herein in its entirety by reference.

### BACKGROUND

### 1. Field

The disclosure relates to a substrate processing device. More specifically, the disclosure relates to a substrate processing device that vapor deposits a polymer on a substrate.

### 2. Description of the Related Art

To manufacture a semiconductor device, a desired pattern is formed on a substrate, such as a wafer and the like, through various processes, such as photolithography, etching, ashing, ion injection, thin film deposition, and the like, performed on the substrate. Various processing liquids and processing gases are used in each process, and particles and process by-products are generated during the process.

In particular, to deposit a desired type of membrane, a deposition method, such as physical vapor deposition (PVD), chemical vapor deposition (CVD), and the like, may be used.

### SUMMARY

Provided is a substrate processing device with improved vapor deposition performance and reliability.

The objectives of the disclosure are not limited to the above-described objective, and other objectives and merits of the disclosure that are not described may be understood from the following embodiments.

According to an aspect of the disclosure, a substrate processing device may be provided. The substrate processing device includes a substrate support portion supporting a substrate, a fluid supply portion arranged above the substrate support portion and configured to supply an initiator and a monomer toward the substrate, and a laser generation portion configured to irradiate a laser in a direction intersecting a direction in which the initiator and the monomer are supplied, and parallel to a surface of the substrate, wherein the initiator and the monomer are polymerized by the laser and deposited on the substrate.

According to another aspect of the disclosure, a substrate processing device may be provided. The substrate processing device may include a substrate support portion supporting a substrate, an injection pipe arranged above the substrate and configured to inject an initiator and a monomer, a plurality of spray pipes configured to spray the initiator and the monomer toward the substrate in a vertically downward direction, and a laser generation portion configured to irradiate a laser in a horizontal direction intersecting the vertically downward direction, wherein the initiator and the monomer are polymerized by the laser and deposited on the substrate.

According to another aspect of the disclosure, a substrate processing device may be provided. The substrate processing device includes a substrate support portion supporting a substrate, a fluid supply portion arranged above the substrate support portion and configured to supply an initiator and a monomer toward the substrate, and a laser generation portion configured to irradiate a laser into the fluid supply portion, wherein the fluid supply portion may further include a first surface in which an injection pipe may be formed, the injection pipe being configured to inject the initiator and the monomer into the fluid supply portion, and a second surface onto which the laser is irradiated, the first surface and the second surface meet each other, and the initiator and the monomer are polymerized by the laser and deposited on the substrate.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic plan view of a substrate processing device according to an embodiment;

FIGS. 2 and 3 are views schematically illustrating a process processing unit of FIG. 1, according to an embodiment;

FIG. 4 is a view schematically illustrating the movement path of a laser irradiated by a laser generator;

FIG. 5 is a view schematically illustrating the process processing unit of FIG. 1 according to another embodiment;

FIGS. 6 to 8 are views schematically illustrating the process processing unit of FIG. 1 according to other embodiments;

FIGS. 9A and 9B are views illustrating air blowers of FIGS. 6 to 8; and

FIGS. 10 and 11 are views schematically illustrating the process processing unit of FIG. 1 according to other embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

The embodiment of the disclosure is described with reference to the accompanying drawings so that one skilled in the art to which the disclosure pertains can work the disclosure. The disclosure does not have to be configured as limited to the embodiments described below and may be embodied in various other forms.

To clearly describe the present embodiments, irrelevant portions to the description are omitted, and in the description with reference to the drawings, the same or corresponding constituents are indicated by the same reference numerals and redundant descriptions thereof are omitted.

Furthermore, in various embodiments, a representative embodiment only is described using the same reference numerals for components having the same configuration, and other embodiments are described in terms of configurations different from the representative embodiment.

In the description of embodiments, when a constituent element “connects” or is “connected” to another constituent element, the constituent element contacts or is connected to the other constituent element “directly” or “through at least one of other constituent elements”. Furthermore, it will be further understood that the terms “comprises” and/or “comprising” used herein specify the presence of stated features or components, but do not preclude the presence or addition of one or more other features or components.

Unless defined otherwise, all terms used herein including technical or scientific terms have the same meanings as those generally understood by those of ordinary skill in the art to which the disclosure may pertain. The terms as those defined in generally used dictionaries are construed to have meanings matching that in the context of related technology and, unless clearly defined otherwise, are not construed to be ideally or excessively formal.

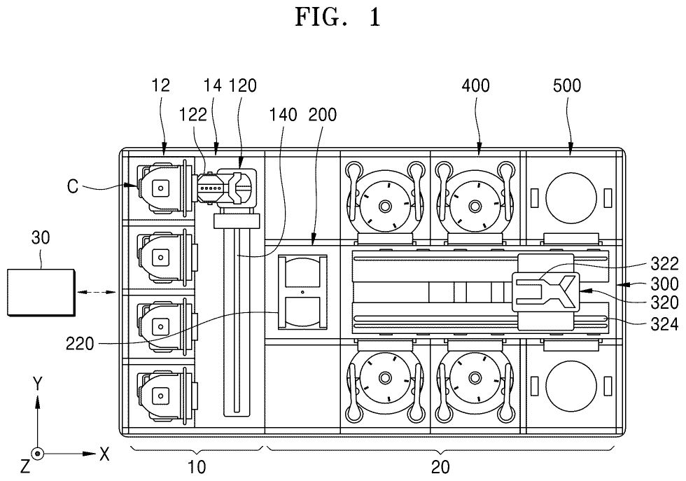

FIG. 1 is a schematic plan view of a substrate processing device according to an embodiment.

Referring to FIG. 1, the substrate processing device may include an index module 10, a processing module 20, and a controller 30. In a top view, the index module 10 and the processing module 20 are arranged along one direction. Hereinbelow, it is assumed that the direction in which the index module 10 and the processing module 20 are arranged is a first direction (X direction), when viewed from the top, a direction perpendicular to the first direction (X direction) is a second direction (Y direction), a direction perpendicular to both of the first direction (X direction) and the second direction (Y direction) is a vertical direction (Z direction).

The index module 10 transfers a substrate W from a container C in which the substrate W is accommodated, to the processing module 20, and accommodates the substrate W that is completely processed in the processing module 20, in the container C. The longitudinal direction of the index module 10 is in the second direction (Y direction). The index module 10 includes a load port 12 and an index frame 14. The load port 12 is located opposite to the processing module 20 with respect to index frame 14. The container C where the substrate WS is accommodated is placed in the load port 12. The load port 12 may include a plurality of load ports, and the load ports 12 may be disposed in the second direction (Y direction).

A sealing container such as a front open unified pod (FOUP) may be used as the container C. The container C may be placed in the load port 12 by a worker or a transfer device (not shown), such as an overhead transfer, an overhead conveyor, or an automatic guided vehicle.

The index frame 14 is provided with an index robot 120. A guide rail 140 of which longitudinal direction is in the second direction (Y direction) is provided in the index frame 14, and the index robot 120 may be provided capable of moving on the guide rail 140. The index robot 120 may include a hand 122 on which the substrate W is disposed, and the hand 122 may be capable of moving forward and backward, rotating around the vertical direction (Z direction) as an axis, and moving along the vertical direction (Z direction). The hand 122 may include a plurality of hands apart from each other in a vertical direction, and the hands 122 may independently move forward and backward.

The controller 30 may control the substrate processing device. The controller 30 may include a process controller including a microprocessor (computer) that performs control of the substrate processing device, a user interface including a keyboard and a display, wherein the keyboard is used to perform a command input manipulation and the like so that an operator manages the substrate processing device, and the display is used to visualize and display the operation status of the substrate processing device, and a memory portion for storing a control program for performing processing performed in the substrate processing device under control of the process controller, a program, that is, processing recipe, to allow each constituent portion to perform processing according to various data and processing conditions. Furthermore, the user interface and the memory portion may be connected to the process controller. The processing recipe may be memorized in a memory medium of the memory portion, and the memory medium may be a hard disk, a portably disc such as CD-ROM, DVD, and the like, and a semiconductor memory such as a flash memory and the like.

The processing module 20 may include a buffer unit 200, a transfer unit 300, a process processing unit 400, and a dry processing unit 500. The buffer unit 200 provides a space in which the substrate W carried into the processing module 20 and the substrate W carried out from the processing module 20 temporarily stay. The process processing unit 400 performs a liquid processing process for liquid processing the substrate W by supplying liquid onto the substrate W. The dry processing unit 500 performs a dry processing process for removing the liquid remaining on the substrate W. The transfer unit 300 transfers the substrate W between the buffer unit 200, the process processing unit 400, and the dry processing unit 500.

In some embodiments, the liquid processing process performed in the process processing unit 400 may include a process of coating the substrate W with a cleaning solvent, and the dry processing process performed in the dry processing unit 500 may include a process of removing the cleaning solvent.

The longitudinal direction of the transfer unit 300 is in the first direction (X direction). The buffer unit 200 may be arranged between the index module 10 and the transfer unit 300. The process processing unit 400 and the dry processing unit 500 may be arranged at a side portion of the transfer unit 300. The process processing unit 400 and the transfer unit 300 may be arranged along the second direction (Y direction). The dry processing unit 500 and the transfer unit 300 may be arranged along the second direction (Y direction). The buffer unit 200 may be locate in one end of the transfer unit 300.

In an example, the process processing unit 400 may be arranged at both sides of the transfer unit 300, the dry processing unit 500 may be arranged at both sides of the transfer unit 300, and the process processing unit 400 may be arranged at a position closer to the buffer unit 200 than the dry processing unit 500 is. At one side of the transfer unit 300, the process processing unit 400 may be arranged in an array of A×B (A and B are each 1 or a natural number greater than 1) in each of the first direction (X direction) and the vertical direction (Z direction). Furthermore, at one side of the transfer unit 300, the dry processing unit 500 may be arranged in an array of C×D (C and D are each 1 or a natural number greater than 1) in each of the first direction (X direction) and the vertical direction (Z direction). Unlike the above description, the process processing unit 400 only may be provided at one side of the transfer unit 300, and the dry processing unit 500 only may be provided at the other side thereof.

The transfer unit 300 has a transfer robot 320. A guide rail 324 having a longitudinal direction in the first direction (X direction) may be provided in the transfer unit 300, and the transfer robot 320 may be capable of moving on the guide rail 324. The transfer robot 320 may include a hand 322 on which the substrate W is disposed, and the hand 322 may be capable of moving forward and backward, rotating around the vertical direction (Z direction) as an axis, and moving along the vertical direction (Z direction). The hand 322 may include a plurality of hands arranged apart from each other in the vertical direction, and the hands 322 may independently move forward and backward.

The buffer unit 200 may include a plurality of buffers on which the substrate W is disposed. The buffers 220 may be arranged apart from each other in the vertical direction (Z direction). A front face and a rear face of the buffer unit 200 are opened. The front face is a surface facing the index module 10, and the rear face is a surface facing the transfer unit 300. The index robot 120 may approach the buffer unit 200 through the front face, and the transfer robot 320 may approach the buffer unit 200 through the rear face.

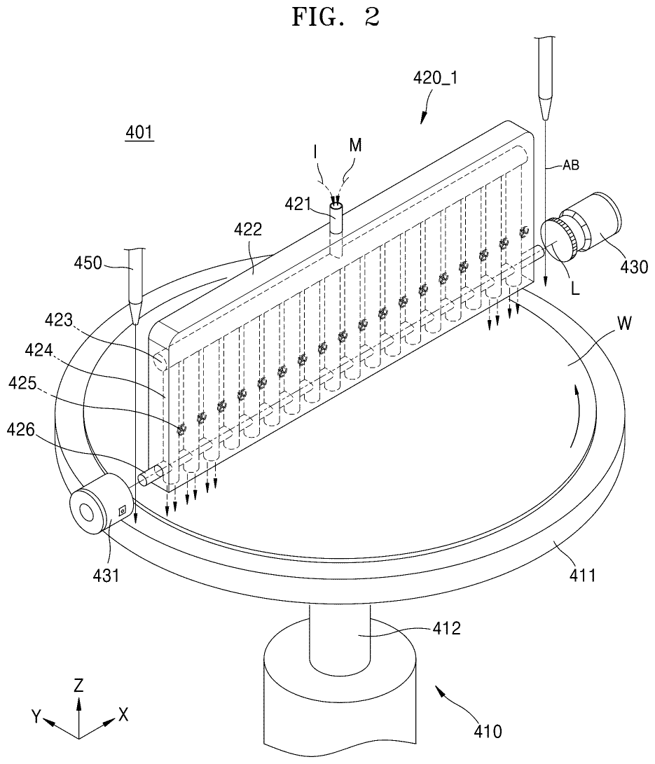

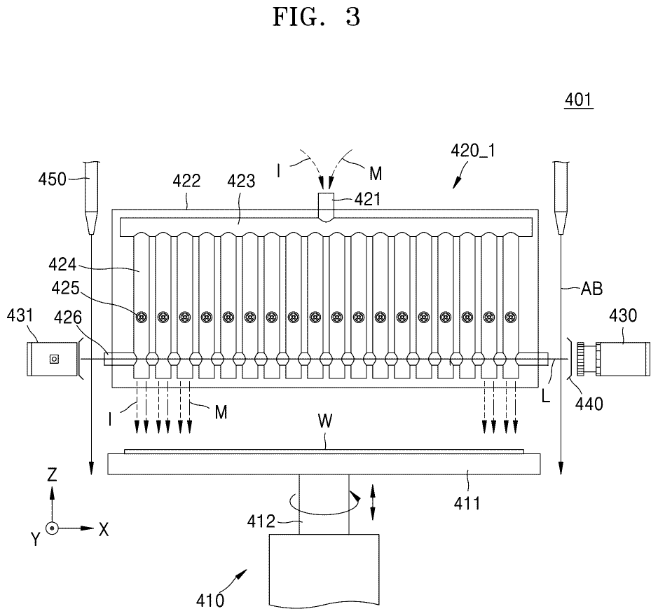

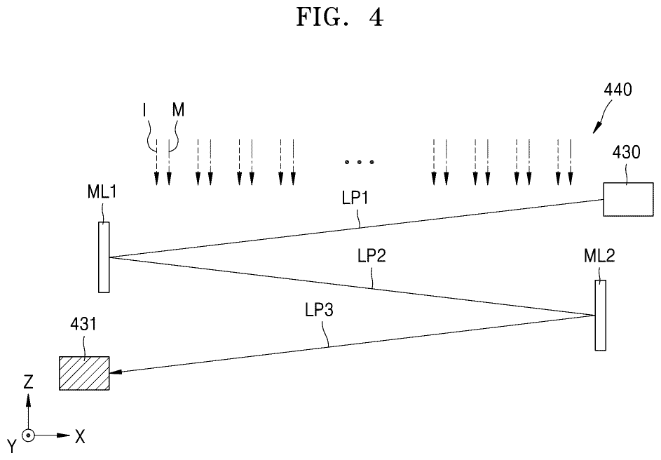

FIGS. 2 and 3 are views schematically illustrating an embodiment of the process processing unit 400 of FIG. 1. In detail, FIG. 2 is a schematic perspective view of a process processing unit 401, and FIG. 3 is a side view of the process processing unit 401 of FIG. 2. FIG. 4 is a view schematically illustrating the movement path of a laser irradiated by a laser generator.

Referring to FIGS. 2 and 3, the process processing unit 401 may include a substrate support portion 410, a fluid supply portion 420_1, a laser generation portion 430, a mirror portion 440, and an air blower 450.

In some embodiments, the substrate support portion 410 may support the substrate W. The substrate support portion 410 may support the substrate W so that fluid supplied from the fluid supply portion 420_1 is deposited on the substrate W. In some embodiments, the substrate support portion 410 may be located under the fluid supply portion 420_1. The substrate support portion 410 may support the substrate W under the fluid supply portion 420_1. The substrate support portion 410 may include a support plate 411 on which the substrate W is disposed. The substrate support portion 410 may include a support 412 for supporting the support plate 411.

In some embodiments, the substrate support portion 410 may rotate the substrate W. The substrate support portion 410 may rotate the substrate W such that the fluid supplied from the fluid supply portion 420_1 is uniformly deposited on the substrate W. The substrate support portion 410 may rotate the substrate W such that the fluid supplied from the fluid supply portion 420_1 is deposited at a particular position on the substrate W. The substrate support portion 410 may rotate the support plate 411 on which the substrate W is disposed. The support 412 may rotate the support plate 411 on which the substrate W is disposed.

In some embodiments, the substrate support portion 410 may move the substrate W in the vertical direction. For example, the substrate support portion 410 may move the substrate W in the vertically upward and/or downward directions. The substrate support portion 410 may move the substrate W in the vertical direction such that the fluid supplied from the fluid supply portion 420_1 is uniformly deposited on the substrate W. The substrate support portion 410 may move the substrate W in the vertical direction such that the fluid supplied from the fluid supply portion 420_1 is deposited at a particular position on the substrate W. The substrate support portion 410 may move, in the vertical direction, the support plate 411 on which the substrate W is disposed. The support 412 may move, in the vertical direction, the support plate 411 on which the substrate W is disposed.

In some embodiments, the fluid supply portion 420_1 may supply the fluid onto the substrate W. In detail, the fluid supply portion 420_1 may supply a fluid that is deposited on the substrate W to form a layer. For example, the fluid supply portion 420_1 may supply an initiator I and a monomer M onto the substrate W.

In some embodiments, the fluid supply portion 420_1 may include an injection pipe 421, a housing 422, a horizontal supply portion 423, a plurality of spray pipes 424, a pressure control valve 425, and a horizontal through pipe 426.

In some embodiments, the injection pipe 421 may be configured to inject the fluid into the fluid supply portion 420_1. In detail, the injection pipe 421 may be configured to inject the initiator I and the monomer M into the fluid supply portion 420_1. For example, the injection pipe 421 may be configured to inject the initiator I and the monomer M supplied toward the substrate W, into the fluid supply portion 420_1. The fluid injected from the injection pipe 421 into the fluid supply portion 420_1 may be, for example, in a gas state. In some embodiments, the injection pipe 421 may inject two or more types of fluids into the fluid supply portion 420_1. For example, the injection pipe 421 may inject a mixture of two or more types of fluids into the fluid supply portion 420_1. For example, the injection pipe 421 may include a plurality of injection pipes, and each of the injection pipes may inject two or more types of fluids. When each of the injection pipes injects two or more types of fluids, the two or more types of fluids may be mixed inside the fluid supply portion 420_1. Alternatively, the two or more types of fluids may be injected separately inside the fluid supply portion 420_1, and then mixed outside the fluid supply portion 420_1 and supplied toward the substrate W.

In some embodiments, the housing 422 may surround components of the fluid supply portion 420_1. The injection pipe 421 may penetrate an outer wall, for example, an upper wall, of the housing 422.

In some embodiments, the horizontal supply portion 423 may extend in a horizontal direction, for example, a first horizontal direction (X direction), and supply the fluid injected from the injection pipe 421 in the horizontal direction in the fluid supply portion 420_1. In some embodiments, the horizontal supply portion 423 may supply the fluid injected from the injection pipe 421 to the spray pipes 424.

In some embodiments, the spray pipe 424 may be configured to spray the fluid toward the substrate W. For example, the spray pipe 424 may be configured to spray the fluid in the vertically downward direction. For example, the spray pipe 424 may be configured to spray the initiator I and the monomer M toward the substrate W. For example, the spray pipe 424 may be configured to spay the initiator I and the monomer M in the vertically downward direction. In some embodiments, the initiator I and/or the monomer M sprayed from the spray pipe 424 may be in a state different from the state of the initiator I and/or the monomer M injected by the injection pipe 421. In detail, the initiator I sprayed from the spray pipe 424 may be in a state different from the state of the initiator I injected by the injection pipe 421. For example, the initiator I sprayed from the spray pipe 424 may be in a state in which the initiator I injected by the injection pipe 421 is radicalized.

In some embodiments, the spray pipe 424 may include a plurality of spray pipes, and the spray pipes 424 may be arranged in a row as long as the horizontal length of the substrate W. For example, the spray pipes 424 may be arranged in the first horizontal direction (X direction).

In some embodiments, the spray pipe 424 may be configured to spray the initiator I and the monomer M, and the initiator I and the monomer M may be polymerized and deposited on the substrate W.

In some embodiments, the pressure control valve 425 may control the pressure of the spray pipe 424. When the fluid supply portion 420_1 includes the spray pipes 424, the pressure control valve 425 may also include a plurality of pressure control valves and control the pressure of each of the spray pipes 424. Each of the pressure control valves 425 may individually the pressure of each of the spray pipes 424. In other words, the pressures in the spray pipes 424 may be controlled to be different from each other.

In some embodiments, the pressure control valve 425 may control the injection speed of the spray pipe 424. When the fluid supply portion 420_1 includes the spray pipes 424, the pressure control valve 425 may also include a plurality of pressure control valves and control the injection speed of each of the spray pipes 424. Each of the pressure control valves 425 may individually control the injection speed of each of the spray pipes 424. In other words, the spray speeds in the spray pipes 424 may be controlled to be different from each other.

In some embodiments, the horizontal through pipe 426 may penetrate the spray pipes 424 in the horizontal direction, for example, the first horizontal direction (X direction). In some embodiments, a laser L is irradiated into the horizontal through pipe 426 so that light and/or heat may be applied to the fluid. In some embodiments, the laser L is irradiated into the horizontal through pipe 426 so that light and/or heat may be applied to the fluid in the spray pipes 424. In some embodiments, the horizontal through pipe 426 may penetrate the outer wall, for example, the side wall, of the housing 422.

In some embodiments, the laser generation portion 430 may irradiate the laser L in a direction parallel to the surface of the substrate W. In detail, the laser generation portion 430 may irradiate the laser L in a direction perpendicular to the fluid supply direction. For example, the laser generation portion 430 may irradiate the laser L in a direction perpendicular to the direction in which the initiator I and the monomer M are supplied. In detail, the initiator I and the monomer M may be supplied in the vertically downward direction, and the laser generation portion 430 may irradiate the laser L in the horizontal direction, for example, the first horizontal direction (X direction).

In some embodiments, the laser generation portion 430 may apply light and/or heat to the fluid by irradiating the laser L thereto. In detail, the laser generation portion 430 may apply light energy and/or heat energy to the fluid by applying the laser L thereto. For example, the laser generation portion 430 may apply light energy and/or heat energy to the initiator I and the monomer M by applying the laser L thereto. For example, the laser generation portion 430 may apply light energy and/or heat energy to the initiator I by applying the laser L thereto, thereby radicalizing the initiator I. In some embodiments, the initiator I radicalized by the laser L may be polymerized with the monomer M and deposited on the substrate W. In other words, the initiator I radicalized by the laser L and the monomer M may be vapor-deposited on the substrate W.

In some embodiments, the laser generation portion 430 may irradiate the laser L to the fluid supply portion 420_1. In detail, the laser generation portion 430 may irradiate the laser L to the inside of the horizontal through pipe 426 of the fluid supply portion 420_1. In some embodiments, when the laser generation portion 430 irradiates the laser L to the inside of the fluid supply portion 420_1, the fluid supply portion 420_1 may supply the initiator I that is radicalized.

In some embodiments, a beam block 431 may be arranged to face the laser generation portion 430 with the fluid supply portion 420_1 therebetween, and may stop the traveling of the laser L. In some embodiments, when the laser L is reflected by the mirror portion 440, the beam block 431 may be arranged at the same side as the laser generation portion 430 based on the fluid supply portion 420_1.

In some embodiments, the mirror portion 440 may reflect the laser L. In detail, the mirror portion 440 may extend the optical path of the laser L by reflecting the laser L. The mirror portion 440 may include at least one mirror. The mirror portion 440 may be located on the traveling path of the laser L and may reflect the laser L.

Referring to FIG. 4, the first and second mirrors ML1 and ML2 may be disposed on the traveling path of the laser L. In detail, a first mirror ML1 may be arranged on a first traveling path LP1 of the laser L irradiated by the laser generation portion 430 and may reflect the laser L. A second mirror ML2 may be arranged on a second traveling path LP2 of the laser L reflected by the first mirror ML1 and may reflect the laser L. The beam block 431 may be arranged on a third traveling path LP3 of the laser L reflected by the second mirror ML2 and may stop the traveling of the laser L. Although FIG. 4 illustrates a case in which the mirror portion 440 includes two mirrors (ML1 and ML2), the number of mirrors of the mirror portion 440 is not limited to the above description, and the arrangement of the beam block 431 is not limited to the above description.

In some embodiments, as described above with reference to FIG. 4, the optical path of the laser L may extend as the mirror portion 440 reflects the laser L. In detail, when a plurality of traveling paths (e.g., LP1-LP3) are formed as the mirror portion 440 reflects the laser L, the energy applied to the initiator I and the monomer M may increase.

In detail, the optical path of the laser L extended by the mirror portion 440 may be overlapped in the direction in which the initiator I and the monomer M are supplied. For example, the initiator I and the monomer M may be supplied in the vertically downward direction, and a plurality of mirrors (ML1 and ML2) of the mirror portion 440 may be arranged to face each other in the horizontal direction, for example, the first horizontal direction (X direction), and thus, the traveling paths LP1-LP3 may overlap each other in the vertical direction (Z direction). In other words, while being supplied in the vertically downward direction, the initiator I and the monomer M may pass along a plurality of traveling paths (e.g., LP1-LP3) and receive the energy of the laser L.

In some embodiments, the air blower 450 may perform an air blowing operation AB between the fluid supply portion 420_1 and the laser generation portion 430. The air blower 450 may perform the air blowing operation AB between the fluid supply portion 420_1 and the laser generation portion 430 to prevent the initiator I and the monomer M from being deposited on the laser generation portion 430.

In some embodiments, the air blower 450 may perform the air blowing operation AB between the fluid supply portion 420_1 and the mirror portion 440. The air blower 450 may prevent the initiator I and the monomer M from being deposited on the mirror portion 440 by performing the air blowing operation AB between the fluid supply portion 420_1 and the mirror portion 440.

In some embodiments, the air blower 450 may perform the air blowing operation AB between the fluid supply portion 420_1 and the beam block 431. The air blower 450 may prevent the initiator I and the monomer M from being deposited on the beam block 431 by performing the air blowing operation AB between the fluid supply portion 420_1 and the beam block 431.

In some embodiments, the air blower 450 may perform the air blowing operation AB in the vertically downward direction. In some embodiments, the air blower 450 may perform the air blowing operation AB in a second horizontal direction (Y direction).

According to some embodiments, a substrate processing device for vapor-depositing a polymer on the substrate W by using the laser L may be provided. In detail, a substrate processing device that vapor-deposits a polymer on the substrate W with the monomer M by radicalizing the initiator I by using the laser L may be provided. According to some embodiments, a substrate processing device including the mirror portion 440 is provided to extend the optical path of the laser L, and accordingly, increase energy may be applied to the initiator I and the monomer M.

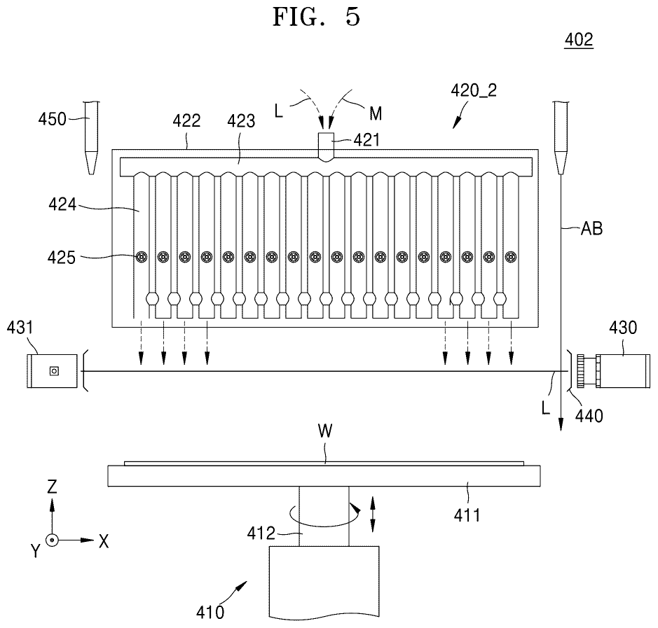

FIG. 5 is a view schematically illustrating another embodiment of the process processing unit 400 of FIG. 1. In detail, FIG. 5 is a side view of a process processing unit 402 in which the laser generation portion 430 irradiates the laser L outside a fluid supply portion 420_2.

Referring to FIG. 5, unlike the process processing unit 401 of FIG. 4, the fluid supply portion 420_2 of the process processing unit 402 may not include a horizontal through pipe 426 (see FIG. 4). The laser generation portion 430 may be disposed at a vertical level lower than the vertical level of the fluid supply portion 420_2. In other words, the laser generation portion 430 may be located at a vertical level between the vertical level of the fluid supply portion 420_2 and the vertical level of the substrate W. Likewise, the beam block 431 and the mirror portion 440 may be located at a vertical level lower than the vertical level of the fluid supply portion 420_2. In other words, the beam block 431 and the mirror portion 440 may be located at a vertical level between the vertical level of the fluid supply portion 420_2 and the vertical level of the substrate W.

In some embodiments, the laser generation portion 430 may apply light and/or heat to the fluid sprayed from the spray pipe 424 by irradiating the laser L outside the fluid supply portion 420_2. In detail, the laser generation portion 430 may apply light energy and/or heat energy to the initiator I and the monomer M sprayed from the spray pipe 424, by irradiating the laser L outside the fluid supply portion 420_2. In this case, the initiator I sprayed from the spray pipe 424 may be radicalized by receiving the light energy and/or heat energy from the outside of the fluid supply portion 420_2 by the laser L. In other words, the initiator I sprayed from the spray pipe 424 may be radicalized by receiving the light energy and/or heat energy from the outside of the fluid supply portion 420_2 by the laser L, and may be polymerized together with the monomer M and deposited on the substrate W.

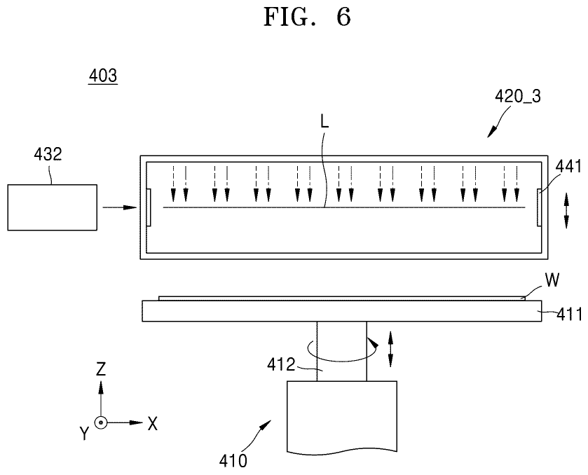

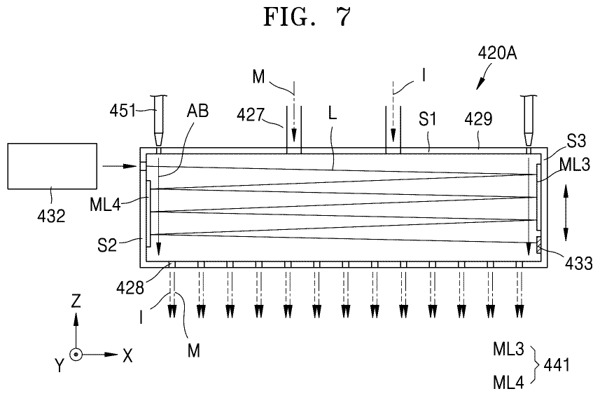

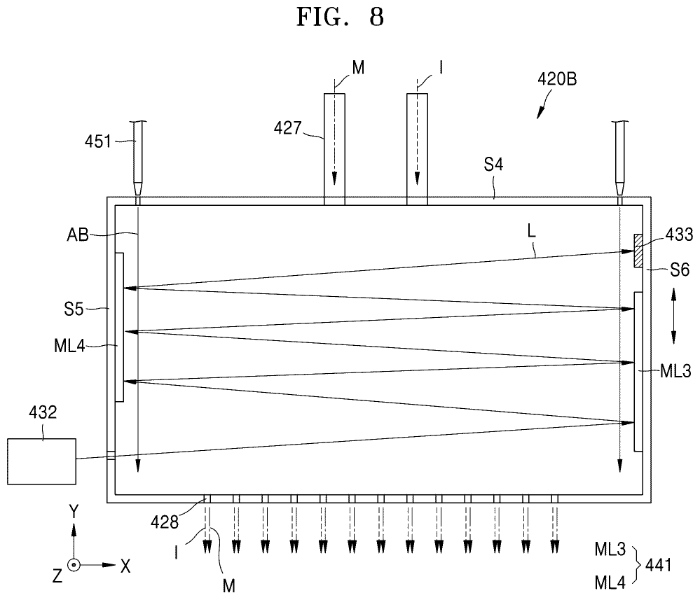

FIGS. 6 to 8 are views schematically illustrating other embodiments of the process processing unit 400 of FIG. 1. In detail, FIG. 6 is a cross-sectional view schematically showing a process processing unit 403, FIG. 7 is a cross-sectional view schematically showing an embodiment 420A of a fluid supply portion 420_3 of the process processing unit 403 of FIG. 6, and FIG. 8 is a plan view schematically showing another embodiment 420B of the fluid supply portion 420_3 of The process processing unit 403 of FIG. 6.

Referring to FIG. 6, the process processing unit 403 may include the substrate support portion 410, the fluid supply portion 420_3, a laser generation portion 432, a mirror portion 441, and an air blower 451. The description of the substrate support portion 410 of FIG. 6 may refer to the description of the substrate support portion 410 with reference to FIGS. 2 and 3.

In some embodiments, the fluid supply portion 420_3 may be disposed above the substrate W and may supply a fluid toward the substrate W. In detail, the fluid supply portion 420_3 may supply a fluid for forming a layer by being deposited on the substrate W. For example, the fluid supply portion 420_3 may supply the initiator I and the monomer M toward the substrate W. In some embodiments, the fluid supply portion 420_3 may move in the vertical direction (Z direction). For example, the fluid supply portion 420_3 may move vertically upward or downward with respect to the substrate W.

In some embodiments, the laser generation portion 432 may irradiate the laser L inside of the fluid supply portion 420_3. In some embodiments, the mirror portion 441 may be located on the traveling path of the laser L and may reflect the laser L. In some embodiments, the air blower 451 may perform the air blowing operation AB and prevent a fluid, for example, the initiator I and the monomer M, from being deposited on the mirror portion 441 and a beam block (not shown). Unlike the fluid supply portion 420_1 described with reference to FIGS. 2 and 3, the mirror portion 441 and the beam block may be arranged inside the fluid supply portion 420_3. The detailed descriptions thereof will be presented below with reference to FIGS. 7 and 8.

Referring to FIGS. 6 and 7 together, a fluid supply portion 420A may include a housing 429, an injection pipe 427, and spray holes 428. The injection pipe 427 may be configured to inject a fluid into the housing 429. In some embodiments, the injection pipe 427 may be configured to inject a mixture of two or more types of fluids into the housing 429. Alternatively, the injection pipe 427 may include a plurality of injection pipes so as to respectively inject two or more types of fluids into the housing 429. In detail, the injection pipe 427 may be configured to inject the initiator I and the monomer M into the housing 429. In some embodiments, the spray hole 428 may be configured to supply a fluid toward the substrate W fluid. For example, the spray hole 428 may be configured to supply the initiator I and the monomer M toward the substrate W. For example, the spray hole 428 may be configured to supply the initiator I and the monomer M, which are radicalized, toward the substrate W.

In some embodiments, the injection pipe 427 may be arranged on a first surface S1 of the housing 429. In some embodiments, the first surface S1 on which the injection pipe 427 is arranged may be an upper wall of the housing 429. In other words, the fluid may be injected in the vertically downward direction into the housing 429 through the first surface S1. When the fluid is injected in the vertically downward direction into the housing 429 through the first surface S1, the spray hole 428 may be arranged on a surface facing the first surface S1, for example, a lower wall of the housing 429.

In some embodiments, the laser generation portion 432 may irradiate the laser L into the fluid supply portion 420A. In detail, the laser generation portion 432 may irradiate the laser L into the housing 429. In detail, the laser generation portion 432 may irradiate the laser L in a direction intersecting the fluid supply direction. In some embodiments, the laser L may be irradiated into the housing 429 through a second surface S2 of the housing 429. In some embodiments, the second surface S2 through which the laser L is irradiated may meet the first surface S1 where the injection pipe 427 is arranged. For example, the second surface S2 may not be in parallel to the first surface S1. For example, the second surface S2 may be a surface that does not face the first surface S1.

In some embodiments, the mirror portion 441 may be arranged inside the fluid supply portion 420A. In detail, the mirror portion 441 may be arranged on an inner wall of the housing 429. The mirror portion 441 may include one or more mirrors. For example, the mirror portion 441 may include a third mirror ML3 and a fourth mirror ML4. In some embodiments, the third mirror ML3 may be arranged on a third surface S3 facing the second surface S2 where the laser L is injected. In some embodiments, the fourth mirror ML4 may be arranged on the second surface S2 where the laser L is injected. In other words, the third mirror ML3 and the fourth mirror ML4 may face each other.

In some embodiments, the mirror portion 441 may extend the optical path of the laser L by reflecting the laser L. In detail, the optical path of the laser L extended by the mirror portion 441 may be overlapped in the direction in which the initiator I and the monomer M are supplied. For example, the initiator I and the monomer M may be supplied in the vertically downward direction, a plurality of mirrors (ML3 and ML4) of the mirror portion 440 may be arranged to face each other in the horizontal direction, for example, the first horizontal direction (X direction) so that a plurality of traveling paths may overlap each other in the vertical direction (Z direction). In other words, while being supplied in the vertically downward direction, the initiator I and the monomer M may pass along a plurality of traveling paths and receive the energy of the laser L.

In some embodiments, a beam block 433 may be arranged on the third surface S3 where the third mirror ML3 is arranged, and may stop the traveling of the laser L. Unlike the illustration, the beam block 433 may be arranged on the second surface S2 where the fourth mirror ML4 is arranged, and may stop the traveling of the laser L. The arrangement of the laser generation portion 432, the beam block 433, and the mirror portion 441 is not limited to the above illustration.

In some embodiments, the air blower 451 may be arranged on the first surface S1 and may perform the air blowing operation AB in the vertically downward direction. The air blower 451 may perform the air blowing operation AB in the vertically downward direction and prevent the fluid from being deposited on the mirror portion 441 and the beam block 433. The arrangement of the air blower 451 is not limited to the above illustration.

Referring to FIGS. 6 and 8 together, a fluid supply portion 420B may include the housing 429, the injection pipe 427, and the spray hole 428. Unlike the fluid supply portion 420A of FIG. 7, the injection pipe 427 of the fluid supply portion 420B may be arranged a fourth surface S4 of the housing 429. In some embodiments, the fourth surface S4 where the injection pipe 427 is arranged may be a side wall of the housing 429. In other words, the fluid may be injected into the housing 429 through the fourth surface S4 in the horizontal direction, for example, in the second horizontal direction (Y direction). When the fluid is injected into the housing 429 through the fourth surface S4 in the second horizontal direction (Y direction), the spray hole 428 may be arranged on a surface facing the fourth surface S4, for example, another side wall of the housing 429. In this case, the fluid sprayed from the spray hole 428 may be sprayed in the second horizontal direction (Y direction) and in the vertically downward direction and deposited on the substrate W.

In some embodiments, the laser L may be irradiated into the housing 429 through a fifth surface S5 of the housing 429. In some embodiments, the fifth surface S5 through which the laser L is irradiated may meet the fourth surface S4 where the injection pipe 427 is arranged. For example, the fifth surface S5 may not be parallel to the fourth surface S4. For example, the fifth surface S5 may be a surface that does not face the fourth surface S4. The fifth surface S5 may be another side wall that meets the fourth surface S4. Although not illustrated, the fifth surface S5 may be an upper wall of the housing 429.

In some embodiments, the mirror portion 441 may extend the optical path of the laser L by reflecting the laser L. In detail, the optical path of the laser L extended by the mirror portion 441 may be overlapped in the direction in which the initiator I and the monomer M are supplied. For example, the initiator I and the monomer M may be supplied in the second horizontal direction (Y direction), and a plurality of mirrors (ML3 and ML4) of the mirror portion 440 may be arranged facing each other in the horizontal direction, for example, the first horizontal direction (X direction), and thus, a plurality of traveling paths may overlap each other in the second horizontal direction (Y direction). In other words, the initiator I and the monomer M may be supplied in the second horizontal direction (Y direction) and may pass along a plurality of traveling paths so as to receive the energy of the laser L.

In some embodiments, the beam block 433 may be arranged on a sixth surface S6 where the third mirror ML3 is arranged, and may stop the traveling of the laser L. Unlike the illustration, the beam block 431 may be arranged on the fifth surface S5 where the fourth mirror ML4 is arranged, and ma stop the traveling of the laser L. The arrangement of the laser generation portion 432, the beam block 433, and the mirror portion 441 is not limited to the above description.

In some embodiments, the air blower 451 may be arranged on the fourth surface S4 and may perform the air blowing operation AB in the vertically downward direction. The air blower 451 may perform the air blowing operation AB in the second horizontal direction (Y direction) and prevent the fluid from being deposited on the mirror portion 441 and the beam block 433. The arrangement of the air blower 451 is not limited to the above illustration.

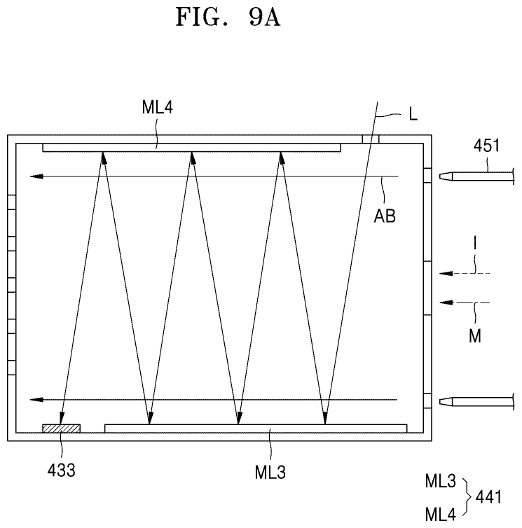

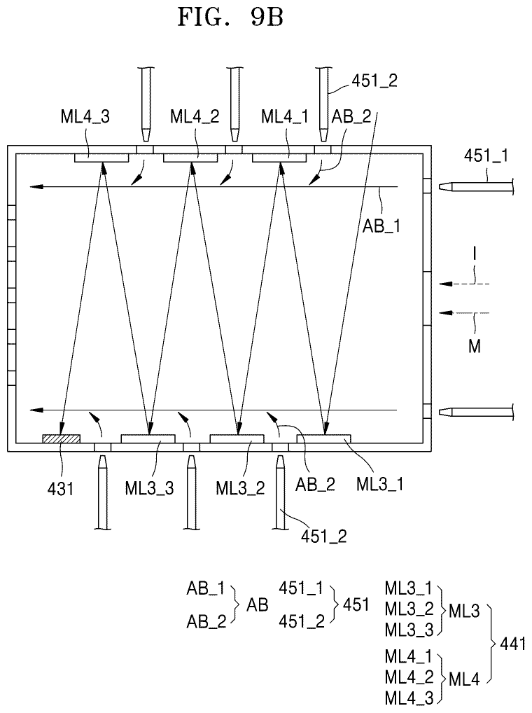

FIGS. 9A and 9B are provided to describe the air blower 451 of FIGS. 6 to 8.

Referring to FIG. 9A, as the air blower 451 performs the air blowing operation AB, the fluid may be prevented from being deposited on the mirror portion 441 and the beam block 433. The air blower 451 may perform the air blowing operation AB in a direction parallel to the surfaces of the mirror portion 441 and the beam block 433.

Referring to FIG. 9B, a main air blower 451_1 and a sub air blower 451_2 are arranged to prevent the fluid from being deposited on the mirror portion 441 and the beam block 433. In detail, the main air blower 451_1 may perform a main air blowing operation AB_1 in a direction parallel to the mirror portion 441 and the beam block 433. In detail, the sub air blower 451_2 may perform a sub air blowing operation AB_2 in a direction intersecting the surfaces of the mirror portion 441 and the beam block 433.

In some embodiments, the third mirror ML3 and/or the fourth mirror ML4 may each include a plurality of mirrors, and the sub air blower 451_2 may perform the sub air blowing operation AB_2 between the plurality of mirrors. In detail, when the third mirror ML3 includes a plurality of third sub mirrors (ML3_1 to ML3_3), the sub air blower 451_2 may perform the sub air blowing operation AB_2 between the plurality of third sub mirrors (ML3_1 to ML3_3) in a direction intersecting the surfaces of the plurality of third sub mirrors (ML3_1 to ML3_3). Likewise, when the fourth mirror ML4 includes a plurality of fourth sub mirrors (ML4_1 to ML4_3), the sub air blower 451_2 may perform the sub air blowing operation AB_2 between the plurality of fourth sub mirrors (ML4_1 to ML4_3) in a direction intersecting the surfaces of the plurality of fourth sub mirrors (ML4_1 to ML4_3).

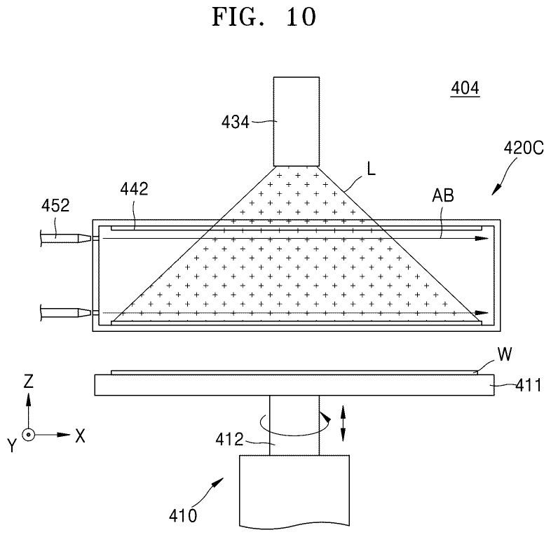

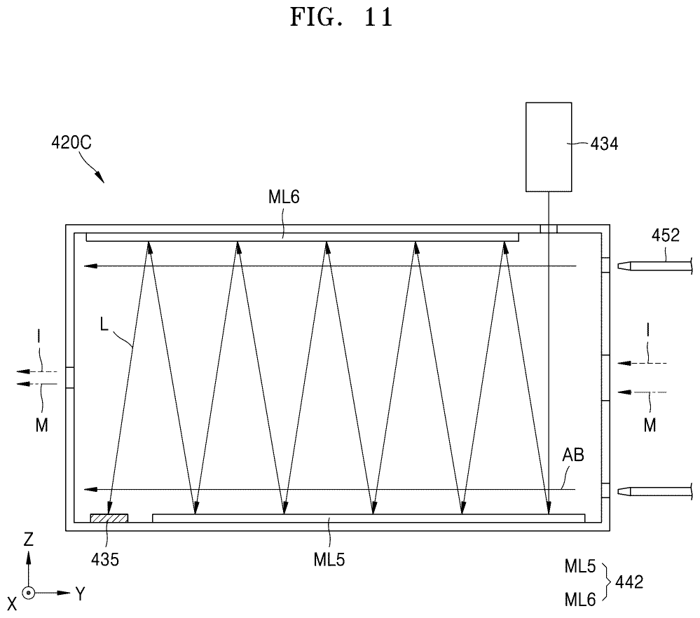

FIGS. 10 and 11 are views schematically illustrating other embodiments of the process processing unit 400 of FIG. 1. In detail, FIG. 10 is a cross-sectional view schematically showing a process processing unit 404, and FIG. 11 is a cross-sectional view schematically showing a fluid supply portion 420C of the process processing unit 404 of FIG. 10.

Referring to FIGS. 10 and 11, the process processing unit 404 may include the substrate support portion 410, the fluid supply portion 420C, a laser generation portion 434, a beam block 435, a mirror portion 442, and an air blower 452. The description of the substrate support portion 410 of FIG. 10 may refer to the description of the substrate support portion 410 with reference to FIGS. 2 and 3.

In some embodiments, the fluid supply portion 420C may be arranged above the substrate W and may supply the fluid toward the substrate W.

In some embodiments, the laser generation portion 434 may irradiate the laser L into the fluid supply portion 420C. Unlike the embodiments described above, the laser generation portion 434 may irradiate the laser L in the form of a plane. In some embodiments, the mirror portion 442 may be located on the traveling path of the laser L and may reflect the laser L. In some embodiments, the air blower 452 may perform the air blowing operation AB and prevent the fluid, for example, the initiator I and the monomer M, from being deposited on the mirror portion 442 and the beam block 435.

In some embodiments, the mirror portion 442 may be arranged inside the fluid supply portion 420C, and may include one or more mirrors. For example, the mirror portion 442 may include a fifth mirror ML5 and a sixth mirror ML6. The fifth mirror ML5 and the sixth mirror ML6 may be arranged to face each other. The mirror portion 441 may extend the optical path of the laser L by reflecting the laser L. In detail, the optical path of the laser L extended by the mirror portion 441 may be overlapped in the direction in which the initiator I and the monomer M are supplied. The beam block 431 may be arranged on the surface where any one of the fifth mirror ML5 and the sixth mirror ML6 is arranged, and may stop the traveling of the laser L. The arrangement of the laser generation portion 434, the beam block 435, and the mirror portion 442 is not limited to the above illustration.

While the disclosure has been particularly shown and described with reference to preferred embodiments using specific terminologies, the embodiments and terminologies should be considered in descriptive sense only and not for purposes of limitation. Therefore, it will be understood by those of ordinary skill in the art that various changes in form and details may be made therein without departing from the spirit and scope of the disclosure as defined by the following claims.

What is claimed is:

1. A substrate processing device comprising:
a substrate support portion supporting a substrate;
a fluid supply portion arranged above the substrate support portion and configured to supply an initiator and a monomer toward the substrate; and
a laser generation portion configured to irradiate a laser in a direction intersecting a direction in which the initiator and the monomer are supplied and parallel to a surface of the substrate,
wherein the initiator and the monomer are polymerized by the laser and deposited on the substrate.

2. The substrate processing device of claim 1, further comprising at least one mirror for reflecting the laser,
wherein the at least one mirror is located on a traveling path of the laser and extends the traveling path of the laser.

3. The substrate processing device of claim 1, further comprising an air blower,
wherein the air blower is configured to perform an air blowing operation to prevent at least one of the initiator and the monomer from being deposited on the laser generation portion.

4. The substrate processing device of claim 1, wherein the initiator is radicalized by the laser, and
a radical of the initiator reacts with the monomer to be polymerized and deposited on the substrate.

5. The substrate processing device of claim 1, wherein the substrate support portion rotates the substrate.

6. The substrate processing device of claim 1, wherein the fluid supply portion comprises a plurality of spray pipes, and
at least one of an spray speed and a pressure of each of the plurality of spray pipes is individually controlled.

7. A substrate processing device comprising:
a substrate support portion supporting a substrate;
an injection pipe arranged above the substrate and configured to inject an initiator and a monomer;
a plurality of spray pipes configured to spray the initiator and the monomer toward the substrate in a vertically downward direction; and
a laser generation portion configured to irradiate a laser in a horizontal direction intersecting the vertically downward direction,
wherein the initiator and the monomer are polymerized by the laser and deposited on the substrate.

8. The substrate processing device of claim 7, wherein the laser generation portion irradiates the laser into the plurality of spray pipes, and
the plurality of spray pipes are configured to spray a radical of the initiator.

9. The substrate processing device of claim 7, wherein the laser generation portion is further configured to irradiate the laser between the plurality of spray pipes and the substrate, and
the initiator and the monomer sprayed from the plurality of spray pipes are polymerized by the laser outside the spray pipe.

10. The substrate processing device of claim 7, wherein at least one of a spray speed and a pressure of each of the plurality of spray pipes is individually controlled.

11. The substrate processing device of claim 7, further comprising at least one mirror for reflecting the laser,
wherein the at least one mirror is located on a traveling path of the laser extends the traveling path of the laser.

12. The substrate processing device of claim 11, further comprising an air blower,
wherein the air blower is configured to perform an air blowing operation to prevent at least one of the initiator and the monomer from being deposited on the at least one mirror.

13. The substrate processing device of claim 12, wherein the air blower performs the air blowing operation in the vertically downward direction.

14. A substrate processing device comprising:
a substrate support portion supporting a substrate;
a fluid supply portion arranged above the substrate support portion and configured to supply an initiator and a monomer toward the substrate; and
a laser generation portion configured to irradiate a laser into the fluid supply portion,
wherein the fluid supply portion further comprises:
a first surface in which an injection pipe is formed, the injection pipe being configured to inject the initiator and the monomer into the fluid supply portion; and
a second surface onto which the laser is irradiated,
the first surface and the second surface meet each other, and
the initiator and the monomer are polymerized by the laser and deposited on the substrate.

15. The substrate processing device of claim 14, further comprising at least one mirror on a third surface facing the second surface,
wherein the at least one mirror extends a traveling path of the laser inside the fluid supply portion by reflecting the laser.

16. The substrate processing device of claim 15, wherein the traveling path of the laser is overlapped in a direction in which the initiator and the monomer are supplied.

17. The substrate processing device of claim 15, further comprising at least one mirror on the second surface.

18. The substrate processing device of claim 15, further comprising a main air blower configured to inject air to pass through a surface of the at least one mirror,
wherein the main air blower is further configured to perform an air blowing operation to prevent at least one of the initiator and the monomer from being deposited on the at least one mirror.

19. The substrate processing device of claim 18, further comprising, when at least two mirrors are on the third surface, a sub air blower configured to perform an air blowing operation between the at least two mirrors.

20. The substrate processing device of claim 14, wherein a traveling path of the laser in the fluid supply portion intersects a direction in which the initiator and the monomer are supplied.
